(19) United States
(12) Patent Application Publication
(10) Pub. No.: US 2003/0002556 A1
(43) Pub. Date: Jan. 2, 2003

(54) Semiconductor laser device, a semiconductor laser array, and a method for aligning optical fibers with the device or array

(75) Inventors: Naoki Tsukiji, Tokyo (JP); Yoshihiro Sato, Tokyo (JP); Masayuki Iwase, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: The Furukawa Electric Co, Ltd., Tokyo (JP)

(21) Appl. No.: 10/175,778

(22) Filed: Jun. 21, 2002

(30) Foreign Application Priority Data
Jun. 22, 2001 (JP) 2001-190120

(51) Int. Cl. H01S 5/00

(52) U.S. Cl. 372/50; 372/46

(57) ABSTRACT

A semiconductor laser device which can be aligned with an optical fiber easily, through visual observation.

The laser device includes at least two active layers which are arranged at the same level relative to a surface of a semiconductor substrate, and parallel to each other with a predetermined space between. One of the active layers has its top face buried under a first semiconductor layer, which has a refractive index lower than the refractive index of that one of the active layers, to form a light emitting portion. Another one of the active layers has its top face buried under an insulating layer, which is a second semiconductor layer different in kind from the first semiconductor layer and the first semiconductor layer in this order, to form a convex non-light-emitting portion.

### BACKGROUND

1. Field of the Invention

The present invention relates to a semiconductor laser device, a semiconductor laser array, and a method of aligning the device or array with an optical fiber. More specifically, it relates to a semiconductor laser device which is suitable as a signal light source for use in data communication, and easy to align with an optical fiber when a semiconductor laser unit is to be assembled.

2. Prior Art

When a semiconductor laser unit which is to be incorporated into an optical communication system is assembled, a semiconductor laser device, which is a light source, and an optical fiber, which is a signal transmission line, need to be optically coupled.

In a semiconductor laser device having a layer structure in which predetermined semiconductor layers are stacked on a semiconductor substrate, a light emitting plane is normally a cleavage plane made by cleaving the layer structure. A minute part of the cleavage plane comprises an active layer, which forms a light emitting portion. The position of the light emitting portion cannot be recognized with the naked eye. Thus, when a laser device and an optical fiber are optically coupled, conventionally they are aligned in the following way:

First, a semiconductor laser device is operated, and one of the end faces of an optical fiber is placed to abut on the light emitting plane of the laser device. Then, while light emitted from the other end face of the optical fiber is being monitored, positional relation between the laser device and the optical fiber are varied three-dimensionally. Then, the laser device and the optical fiber are fixed in the positional relation where the monitored light has maximal intensity.

However, this way of aligning is not necessarily industrial in that it is rather cumbersome and requires high skill.

Thus, study has been made of an aligning technique by which a laser device and an optical fiber can be aligned easily and stably and optical coupling can be made with high reliability.

For example, Japanese Patent Unexamined Publication No. Hei 7-50449 discloses a semiconductor laser device which can be aligned with an optical fiber through visual observation.

In this semiconductor laser device, two active layers are arranged in a predetermined positional relation, in a semiconductor layer structure formed on a semiconductor substrate. The upper portion of one of the two active layers is buried under semiconductor layers and the part thus made of functions as a regular light emitting portion. Of the other active layer, only the upper portion is not buried under semiconductor layers, and a V-shaped groove which is recognizable with the eye is formed in a position corresponding to that upper portion. The part thus made of forms a non-light-emitting portion, and the V-shaped groove functions as a marker portion.

When this laser device is to be optically coupled to an optical fiber, first, through visual observation, an end face of the optical fiber is aligned with the bottom of the marker portion of the non-light emitting portion. Then, the optical fiber is displaced parallel, in the width direction of the laser device, by a predetermined distance. Thus, the optical fiber is aligned with the active layer of the light emitting portion.

In this known technique, however, when crystals of semiconductor materials are made to grow in order to form a V-shaped groove (marker portion) which is a non-light emitting portion, abnormal growth can happen and polycrystals can be formed in the V-shaped groove. In that case, the V-shaped groove has a rough surface, which prevents the V-shaped groove from being clearly recognized with the eye.

Further, there may happen a problem that, when an electrode is formed over the light emitting portion, the electrode extends over the marker portion (V-shaped groove), which easily causes short-circuiting.

### OBJECTS AND SUMMARY OF THE INVENTION

An object of the present invention is to solve the above problems with the prior art and provide a semiconductor laser device of a structure such that a non-light-emitting portion is recognized better with the eye, an electrode can be formed over a light emitting portion stably, and the semiconductor laser is easily aligned with an optical fiber.

Another object of the present invention is to provide a semiconductor laser array in which above-described semiconductor laser devices of the present invention are arranged on a single semiconductor substrate.

Another object of the present invention is to provide a method of aligning an above-described laser device or laser array with an optical fiber, by which the laser device or laser array and the optical fiber can be optically coupled stably and with high reliability.

In order to attain the above objects, the present invention provides a semiconductor laser device, comprising:

a semiconductor substrate;

at least two active layers arranged at the same level relative to a surface of the semiconductor substrate, and parallel to each other with a predetermined space between;

a light emitting portion comprising one of said active layers, a first semiconductor layer which has a refractive index lower than the refractive index of said one of the active layers, and an insulating layer which is a second semiconductor layer different in kind from the first semiconductor layer, where the upper portion of said one of the active layers is buried under the first semiconductor layer and side portions of said one of the active layers are buried in said insulating layer; and

a non-light-emitting portion having a convex shape as a whole, comprising another one of said active layers, said second semiconductor layer and said first semiconductor layer, where the upper portions and side portions of said another one of the active layers are buried under said second semiconductor layer, and said second semiconductor layer is buried under said first semiconductor layer.

The present invention further provides a semiconductor array, comprising:

a single semiconductor substrate; and

above-described light emitting portions and non-light-emitting portions, which are arranged on the single semiconductor substrate alternately.

The present invention further provides a method of aligning a semiconductor laser device and an optical fiber, wherein

while a two-dimensional shape of a convex non-light-emitting portion of an above-described semiconductor laser device or an above-described semiconductor laser array is being observed, an active layer of a light emitting portion and the central axis of an optical fiber are aligned.

The present invention further provides a method of aligning a semiconductor laser device and an optical fiber, wherein

while a two-dimensional shape of a convex non-light-emitting portion of an above-described semiconductor laser device or an above-described semiconductor laser array is being observed, an active layer of the non-light-emitting portion and the central axis of an optical fiber are aligned, and then

the optical fiber is displaced parallel, in the width direction of the non-light-emitting portion, by a predetermined distance.

### BRIEF DESCRIPTION OF THE DRAWINGS

FIG. 1 is a perspective view of an example of a layer structure of a laser device according to the present invention;

FIG. 2 is a perspective view showing how mesa stripes A₀, B₀ are formed on a substrate;

FIG. 3 is a perspective view showing the mesa stripe B₀ of FIG. 2 from which a mask has been removed;

FIG. 4 is a perspective view showing how a current blocking layer (second semiconductor layer) is formed;

FIG. 5 is a perspective view showing how a cladding layer and a contact layer (which compose a first semiconductor layer) are formed;

FIG. 6 is a cross-sectional view of an example of a layer structure of another semiconductor laser device according to the present invention;

FIG. 7 is a cross-sectional view of an example of a layer structure of another semiconductor laser device (SAS type) according to the present invention;

FIG. 8 is a perspective view of an example of a semiconductor laser array according to the present invention;

FIG. 9 is a perspective view for explaining how the laser device of FIG. 1 and an optical fiber are aligned;

FIG. 10 is a perspective view for explaining how the laser device of FIG. 6 and an optical fiber are aligned;

FIG. 11 is a perspective view for explaining another way of aligning the laser device of FIG. 1 and an optical fiber; and

FIG. 12 is an illustration showing how a mesa of the laser device is placed relative to a marker portion, in the aligning of FIG. 11.

### DETAILED DESCRIPTION

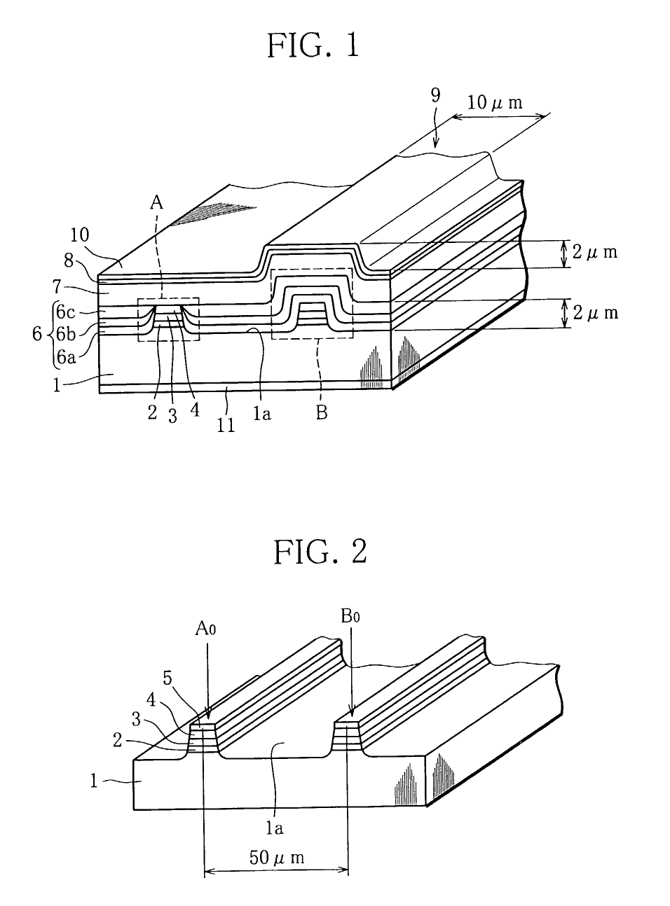

FIG. 1 shows an example of a layer structure of a laser device according to the present invention. First, referring to the drawings, how this example of a laser device is produced will be described.

First, for example, on the (100) plane of a p-InP substrate 1, a buffer layer 2 of, for example, p-InP, an active layer 3 of, for example, GRIN-SCH-MQW structure (InGaAsP), and a cladding layer 4 of, for example, n-InP are stacked in this order to thereby form a slab layer structure. Next, by applying photolithography to the surface of the slab layer structure, dielectric masks 5 of, for example, SiNₓ are formed in the form of stripes extending along the (110) plane. Then, by etching, two mesa stripes A₀, B₀ which are parallel to each other with a space of, for example, 50 μm distance are formed, as shown in FIG. 2.

Thus, the buffer layer 2, active layer 3, cladding layer 4 and dielectric mask 5 of the mesa stripe A₀ and those of the mesa stripe B₀ are the same in thickness, respectively. Then, the mesa stripe A₀ will be formed into a light emitting portion, while the other mesa stripe B₀ will be formed into a non-light-emitting portion.

Here, the active layer 3 of the mesa stripe A₀ and the active layer 3 of the mesa stripe B₀ are at the same level relative to the surface 1a of the p-InP substrate 1.

The width of each active layer is 2 μm or so. The centerlines of both active layers, each bisecting the width of the active layer, run along the (110) plane and parallel to each other with a predetermined space (50 μm) distance. This space between the centerlines is determined uniquely by the distance between the dielectric mask stripes which are formed on the surface of the slab layer structure.

This means that, at the time the mesa stripes A₀ and B₀ are formed, positional relation between the two active layers of the device are determined uniquely.

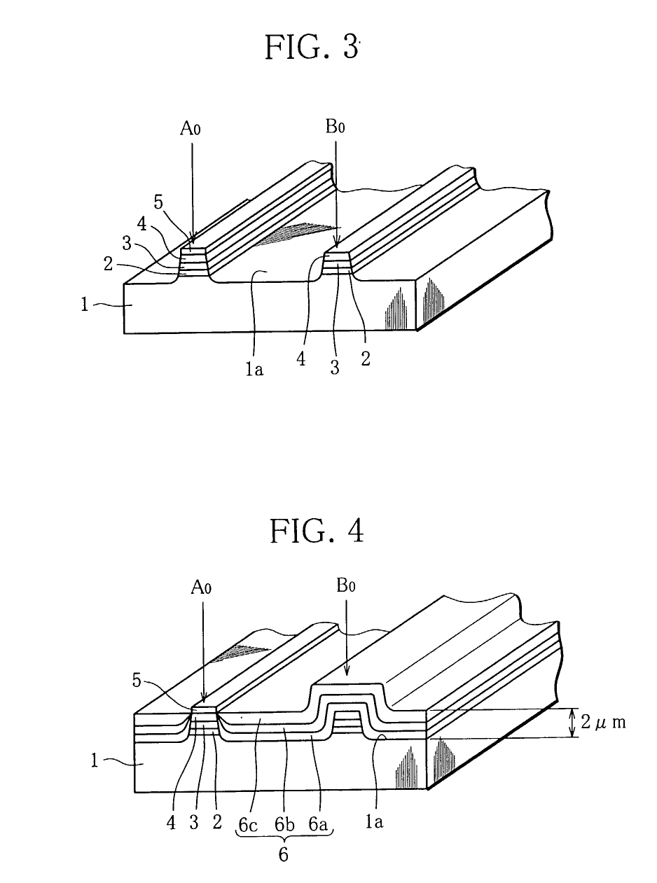

Next, as shown in FIG. 3, only the dielectric mask on the mesa stripe B₀ is removed by etching to thereby have the cladding layer 4 exposed. The dielectric mask on the mesa stripe A₀ is left, in order to use it as a mask for selective growth. Next, crystal growth is carried out.

Specifically, a buried layer 6a of p-InP, a buried layer 6b of n-InP, and a buried layer 6c of p-InP are stacked in this order.

As a result, as shown in FIG. 4, a current blocking layer 6 of p/n/p junction structure which is, for example, 2 μm in thickness is formed, where the mesa stripe A₀ has only both side portions thereof buried in the current blocking layer.

The mesa stripe B₀, from which the dielectric mask has been removed, has the upper portion and both side portions thereof buried under the layer 6 of p/n/p junction structure.

At this time, the whole thickness of the mesa stripe B₀ as measured from the surface 1a of the p-InP substrate 1 is larger than the thickness of the mesa stripe A₀ excluding the dielectric mask 5, by an amount corresponding to the thickness of the layer of p/n/p junction structure, i.e., the current blocking layer 6 (2 μm). Thus, the mesa stripe B₀ projects upward more than the mesa stripe A₀ does.

Next, the dielectric mask 5 on the mesa stripe A₀ is removed by etching to thereby have the cladding layer 4 exposed. Then, crystals of semiconductor materials having a refractive index lower than that of the semiconductor material (InGaAsP) of which the active layer 3 is made are made to grow over the entire surface of the device. Specifically, for example, a cladding layer 7 of n-In P and a contact layer 8 of n-InGaAsP are stacked in this order.

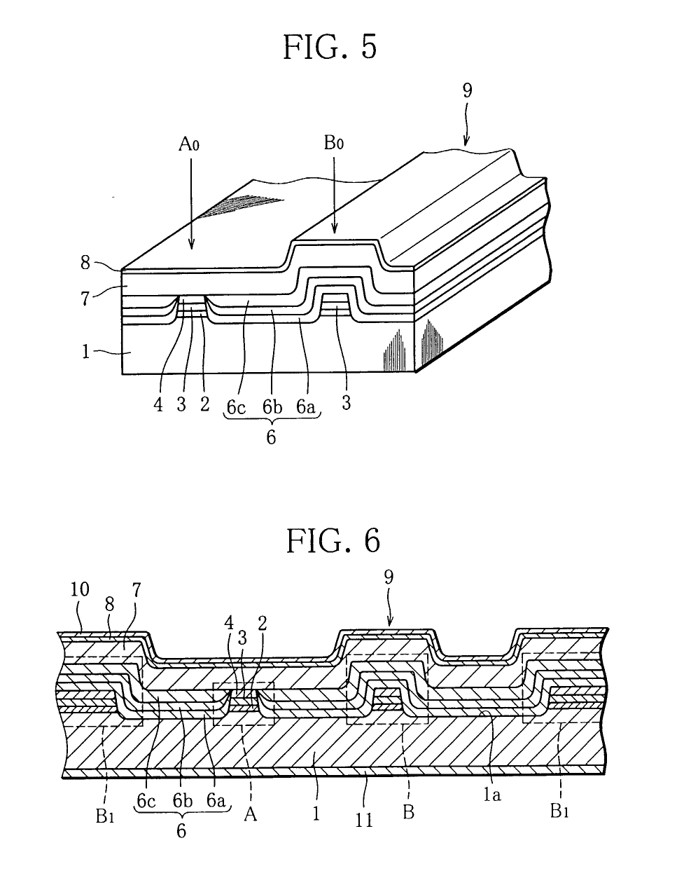

As a result, as shown in FIG. 5, the top face of the mesa stripe A₀ is buried under the two layers, i.e., the cladding layer 7 and the contact layer 8, so that a layer structure having a flat surface forms there.

The mesa stripe B₀ becomes a trapezoidal mesa 9 which has the above-mentioned two layers added to the mesa stripe B₀ of FIG. 4.

Last, an n-type electrode 10 is formed on the contact layer 8, and a p-type electrode 11 is formed on the backside of the p-InP substrate 1. Thus, the semiconductor laser device shown in FIG. 1 is completed.

In the laser device of FIG. 1, the mesa 9 is 10 μm in width and 2 μm in height.

In the present invention, in the layer structure shown in FIG. 1, the low refractive index semiconductor layer which is formed directly on the cladding layer 4 of the mesa stripe A₀ to have the mesa stripe A₀ buried under itself (the layer consisting of the n-cladding layer 7 and the n-contact layer 8) is called a first semiconductor layer.

Between the first semiconductor layer and the cladding layer 4 of the mesa stripe B₀ exists the layer 6 which functions as a current blocking layer for the active layer of the mesa stripe A₀. In the present invention, this layer is called a second semiconductor layer.

In the laser device of this structure, first, when the n-type electrode 10 and the p-type electrode 11 are operated, current is injected into the active layer 3 of the mesa stripe A₀. Thus, the laser starts to operate, and a part A functions as a light emitting portion.

In contrast, since current injection into the active layer of the mesa stripe B₀ is blocked by the current blocking layer 6 (second semiconductor layer), a part B functions as a non-light-emitting portion.

When the entire top face of the laser device is observed with the eye, only the convex mesa 9 looks bright at its top face and a little darker at both side portions thereof. Thus, a bright part with two dark lines which run parallel to each other with a space of about 10 μm between, on both sides of the bright part can be recognized as the two-dimensional shape of the mesa 9.

The active layer of the non-light-emitting portion B is located at the center of the width of this bright part. Thus, the two-dimensional position of the active layer can be recognized with the eye, from above.

Though the vertical position of the active layer cannot be recognized directly, it can be recognized in the following way:

First, when the surface of the n-type electrode 10 in the mesa 9 is chosen as a reference point, the vertical position of the active layer in the non-light-emitting portion B can be easily recognized.

Specifically, when the surface of the n-type electrode 10 in the mesa 9 is chosen as a reference point, the top face of the active layer is at a level corresponding to the height of the reference point minus the respective thicknesses of the n-type electrode, contact layer 8, cladding layer 7, second semiconductor layer 6 and cladding layer 4, and those thicknesses are all given.

Thus, the three-dimensional position of the active layer in the non-light-emitting portion B can be recognized through visual observation of the top face of the laser device.

The active layer in the light emitting portion A is apart from the active layer in the non-light-emitting portion B, by a predetermined distance (50 μm) in the width direction of the laser device.

Thus, when the three-dimensional position of the active layer in the non-light-emitting portion B is recognized in the above-described way, the position of the active layer in the light emitting portion A can be recognized, because, if the position of the active layer in the non-light-emitting portion B is displaced parallel by 50 μm in the width direction of the laser device, that is the position of the active layer in the light emitting portion A.

Thus, when the semiconductor device is to be aligned with an optical fiber, first, the optical fiber is aligned with the active layer of the non-light-emitting portion B, through visual observation or pattern recognition. Then, the optical fiber which has been aligned with the active layer of the non-light-emitting portion B is displaced parallel by a predetermined distance (distance between the dielectric mask stripes). Only with this, the optical fiber and the active layer 3 of the light emitting portion A are aligned with each other.

FIG. 6 is a cross-sectional view of another laser device according to the present invention.

In this laser device, the same layer structures B₁, B₁ as that of the non-light-emitting portion B are so formed that the light emitting portion A and non-light-emitting portion B of the laser device shown in FIG. 1 are located between them. Thus, the mesa 9 of the non-light-emitting portion B and the layer structures (non-light-emitting portions) B₁, B₁ located on both sides of the non-light-emitting portion B have the same height as measured from the surface 1a of the substrate 1.

As compared with the laser device shown in FIG. 1, this laser device is superior in the following:

In the case of the laser device of FIG. 1, if it is turned upside down and bonded to, for example, a heat sink (junction-down bonding), stability may become worse due to the difference in height between the light emitting portion A and the non-light-emitting portion B (mesa 9). In contrast, in the case of the laser device shown in FIG. 6, the two non-light-emitting portions B₁, B₁ of the same height provided on both sides of the light emitting portion A and non-light-emitting portion B ensure good stability.

It is to be noted that when the laser device is bonded, the indentations of 2 μm in depth between the mesa 9 and the layer structures B₁, B₁ cause no trouble, since they are filled with bonding solder.

Though it is preferable to form non-light emitting portions B₁ on both sides of the light-emitting portion A, it is acceptable to form a non-light emitting portions B₁ on one side of the light emitting portion A or non-light-emitting portion B.

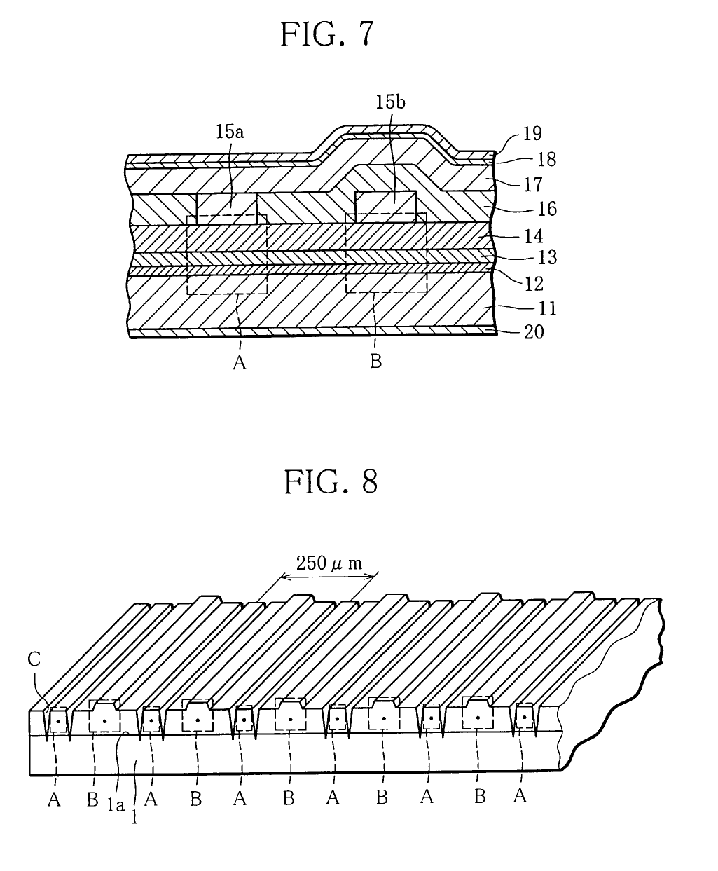

FIG. 7 is a cross-sectional view of another laser device according to the present invention. This laser device is an SAS (Self-Alignment Semiconductor) type laser device.

In this laser device, on a semiconductor substrate 11 of, for example, n-InP, a buffer layer 12 of, for example, n-InP, an active layer 13 of GRIN-SCH-MQW structure (InGaAsP), and a first cladding layer 14 of p-InP are stacked in this order.

On the first cladding layer 14, two second cladding layers 15a, 15b of p-InP are arranged parallel to each other with a predetermined space between.

One 15a of the second cladding layers is buried in a current blocking layer 16, except its top face. That is, both side portions of the second cladding layer 15a are buried in the current blocking layer 16. The other second cladding layer 15b is buried under the current blocking layer 16, including the top face and both side portions thereof, and the whole including the current blocking layer 16 and the second cladding layer 15b takes a convex shape.

On the entire top face of the current blocking layer 16, a third cladding layer 17 of, for example, p-InP, and a contact layer 18 of p-InGaAsP are stacked in this order. A p-type electrode 19 is formed on the contact layer 18, while an n-type electrode 20 is formed on the backside of the substrate 11.

In this laser device, the third cladding layer 17 and the contact layer 18 form a first semiconductor layer of the present invention, and the current blocking layer 16 forms a second semiconductor layer.

A light emitting portion A is located under the second cladding layer 15a, and a non-light-emitting portion B is formed under the second cladding layer 15b. The part over the non-light-emitting portion B has a convex shape.

Thus, this semiconductor device according to the present invention is so formed that the convex part including the non-light-emitting portion, which includes an active layer at the same level as the active layer of the light emitting portion, projects from the surface of the other part of the semiconductor device. Thus, when the surface of the semiconductor device is observed with the eye or pattern-recognized, the part including the non-light-emitting portion is recognized as a shadowed portion. Thus, the non-light-emitting portion functions as a marker portion.

FIG. 8 is a perspective view of an example of a semiconductor laser array according to the present invention.

In this semiconductor laser array, light emitting portions A and non-light-emitting portions B as described above are arranged alternately on a single semiconductor substrate 1.

Between the light emitting portions A and non-light-emitting portions B, trenches C having a depth to reach the semiconductor substrate 1 are formed on both sides of each light emitting portion A, to keep the insulation between the light emitting portions A and non-light-emitting portions B. The pitch between the light emitting portions A is generally 250 μm or so.

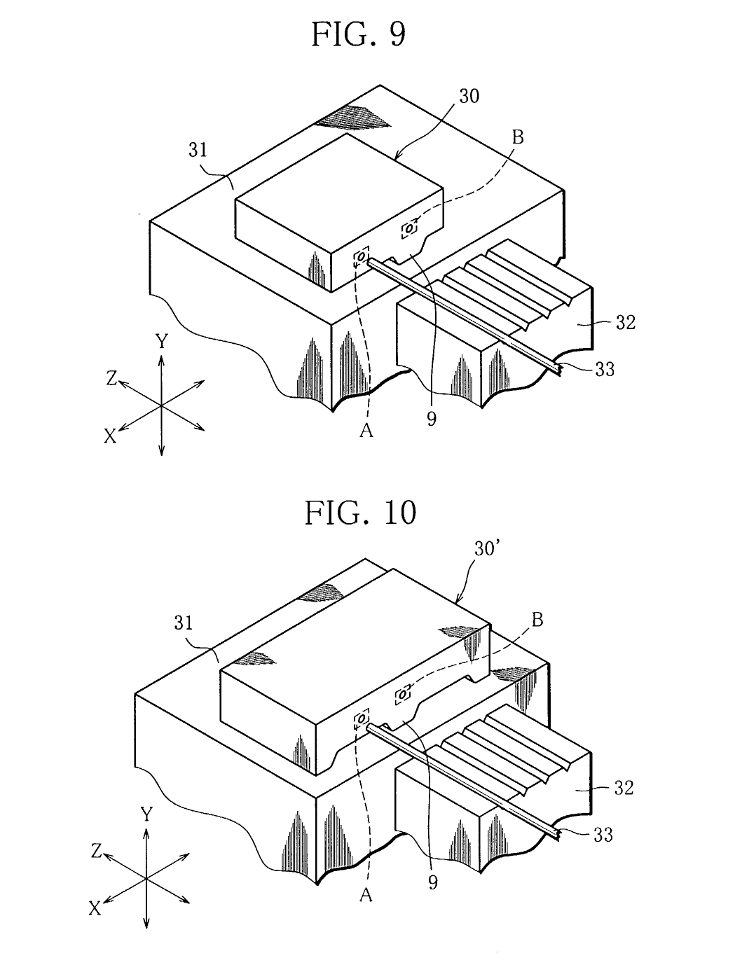

Next, referring to FIG. 9, an aligning method will be described.

FIG. 9 shows a method of aligning a laser device of the type shown in FIG. 1 with an optical fiber, after the laser device is junction-down bonded to a heat sink.

First, a laser device 30 is junction-down bonded to a heat sink 31. Here, the space due to the difference between the level of the surface of the mesa 9 located under the non-light emitting portion B and the level of the surface of the part located under the light emitting portion A is filled with solder. Thus, the laser device 30 is arranged in a horizontal position. An optical fiber 33 is placed in a V-shaped groove in a support table 32. Then, the support table 32 is moved in Y direction so that the central axis of the optical fiber will be at the level of the surface (bonding surface) of the mesa 9 of the laser device 30 (not shown).

Then, from under the heat sink, the two-dimensional shape of the mesa 9 of the laser device 30 is pattern-recognized using, for example, an infrared camera, to thereby recognize the width of the mesa 9. After the width of the mesa 9 is recognized, the support table is moved in X direction so that the central axis of the optical fiber will be at the center of the width of the mesa 9. Thus, in respect of X direction, the optical fiber 33 has been placed in a position corresponding to the active layer of the non-light-emitting portion B.

Next, the support table 32 is moved in Y direction, by a predetermined distance, from the surface of the mesa 9. The distance by which the support table should be moved is grasped in advance, as the total thickness of the layers stacked on the active layer. Thus, in respect of Y direction, the optical fiber 33 has been placed in a position corresponding to the active layer of the non-light-emitting portion B.

Last, the support table 32 is moved in X direction by a predetermined distance. The distance by which the support table should be moved is grasped in advance, as the distance between the mesa stripes A₀ and B₀.

With this movement, the central axis of the optical fiber 33 is aligned with the active layer of the light emitting portion A, accurately.

FIG. 10 shows a method of aligning a laser device of the type shown in FIG. 6 with an optical fiber. In this case, aligning is carried out in the same way as described with respect to FIG. 9.

FIG. 11 shows another method of aligning a laser device according to the present invention.

In this method, a heat sink 31 as described below is prepared.

On the surface of the heat sink 31, a metallic maker portion 34 for positioning, which is smaller in width than the mesa 9 of a laser device 30, is formed, for example, by photolithography. 50 μm apart from the marker portion 34, a V-shaped groove 35, in which an end portion of an optical fiber 33 is to be placed, is formed. In another area of the surface of the heat sink 31, a metallization pattern 36 is printed for bonding of the laser device 30.

In order to align the laser device, first, the mesa 9 of the laser device 30 is placed in a predetermined position on the marker portion 34. Specifically, the laser device 30 is placed on the surface of the heat sink 31 so that the mesa 9 will be on the marker portion 34. Then, positional relation between the mesa 9 and the marker portion 34 is observed from under the heat sink 31, using an infrared lamp.

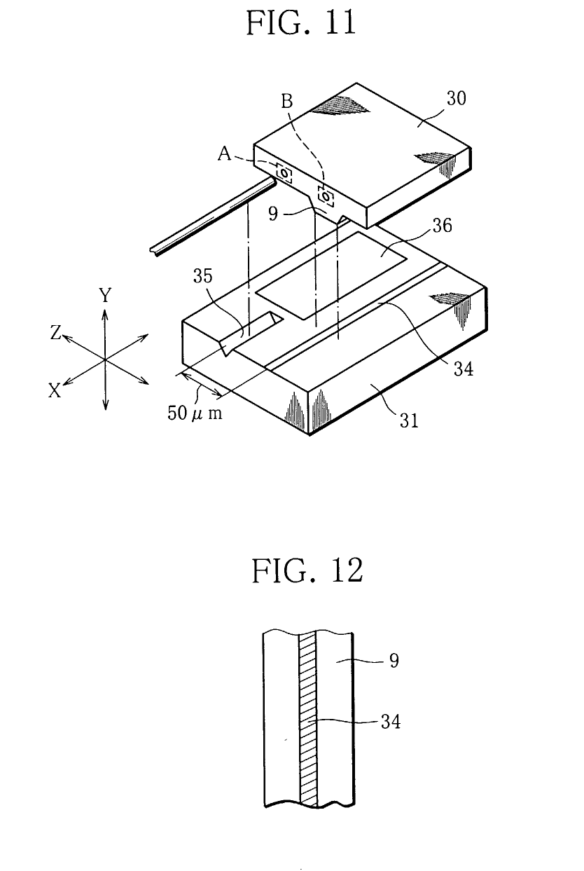

The mesa 9 looks relatively bright, while the marker portion 34 looks dark. Since the marker portion 34 is smaller in width than the mesa 9, the maker portion 34 and the mesa 9 are observed as shown in FIG. 12. That is, it looks like the marker portion 34 is located within the width of a bright line which is the mesa 9.

While being observed, the laser device 30 is displaced a little in Z direction, and when the maker portion 34 comes to the center in width of the mesa 9, the laser device 30 is fixed. At that time, the center in Z direction of the active layer of the non-light-emitting portion B corresponds to the center in Z direction of the marker portion 34.

Then, when the optical fiber 33 is placed in the V-shaped groove 35, the central axis of the optical fiber 33 comes in a position which is 50 μm apart from the non-light-emitting portion B. This means that the central axis of the optical fiber 33 is automatically aligned with the active layer of the light emitting portion A of the laser device 30.

Thus, the laser device according to the present invention is easy to align with an optical fiber. Further, the laser device of the present invention is useful as a light source suited to be incorporated into a semiconductor laser unit. Further, in the process of producing the laser device of the present invention, abnormal growth such as formation of polycrystals, which has been mentioned with respect to the prior art, does not happen. Thus, the laser device stably has a good shape. Further, even when an electrode is formed over the light emitting portion, there is no risk of short-circuiting, which has been mentioned with respect to the prior art, because the active layer of the non-light-emitting portion is already buried. Thus, the electrode is formed stably.

What is claimed is:

1. A semiconductor laser device, comprising:
a semiconductor substrate;
at least two active layers arranged at the same level relative to a surface of the semiconductor substrate, and parallel to each other with a predetermined space between;
a light emitting portion comprising one of said active layers, a first semiconductor layer which has a refractive index lower than the refractive index of said one of the active layers, and an insulating layer which is a second semiconductor layer different in kind from the first semiconductor layer, where the top face of said one of the active layers is buried under said first semiconductor layer and side portions of said one of the active layers are buried in said insulating layer; and
a non-light-emitting portion having a convex shape as a whole, comprising another one of said active layers, said second semiconductor layer and said first semiconductor layer, where the top face and side portions of said another one of the active layers are buried under said second semiconductor layer, and said second semiconductor layer is buried under said first semiconductor layer.

2. The semiconductor laser device according to claim 1, comprising at least two of said non-light-emitting portions.

3. A semiconductor laser array, comprising:
a single semiconductor substrate, and
light emitting portions and non-light-emitting portions according to claim 1 which are arranged on said single semiconductor substrate alternately.

4. The semiconductor laser array according to claim 3, wherein trenches having a depth to reach said semiconductor substrate are formed between said light emitting portions and non-light-emitting portions.

5. A method of aligning a semiconductor laser device and an optical fiber, wherein
while a two-dimensional shape of a convex non-light-emitting portion of a semiconductor laser device according to claim 1 or a semiconductor laser array according to claim 3 is being observed, an active layer of a light emitting portion and the central axis of an optical fiber are aligned.

6. The method of aligning a semiconductor laser device and an optical fiber according to claim 5, wherein
after an active layer of the non-light-emitting portion and the central axis of the optical fiber are aligned, the optical fiber is displaced parallel, in the width direction of the non-light-emitting portion, by a predetermined distance.
